(19) United States
(12) Patent Application Publication
(10) Pub. No.: US 2024/0381695 A1
(43) Pub. Date: Nov. 14, 2024

(54) DISPLAY DEVICE

(71) Applicant: Samsung Display Co., LTD., Yongin-si (KR)

(72) Inventors: Kyoung Jin PARK, Yongin-si (KR); Chang Kyu JIN, Yongin-si (KR); Sung Hwan KIM, Yongin-si (KR)

(73) Assignee: Samsung Display Co., LTD., Yongin-si (KR)

(21) Appl. No.: 18/424,302

(22) Filed: Jan. 26, 2024

(30) Foreign Application Priority Data
May 12, 2023 (KR) 10-2023-0062015

(51) Int. Cl. H10K 59/121; G09G 3/32; H10K 59/131

(52) U.S. Cl. CPC H10K 59/1216; G09G 3/32; H10K 59/131; G09G 2300/0426; G09G 2300/0819; G09G 2300/0852; G09G 2320/0238

(57) ABSTRACT

A display device includes a first electrode of a boost capacitor, disposed on a base layer, a second electrode of the boost capacitor, disposed on the first electrode of the boost capacitor, a gate electrode of a driving transistor, disposed on the base layer, and a connection electrode electrically connecting the gate electrode of the driving transistor and the second electrode of the boost capacitor to each other. The second electrode of the boost capacitor is disposed between the first electrode of the boost capacitor and the connection electrode, and the gate electrode of the driving transistor and the first electrode of the boost capacitor are disposed in a same layer.

### CROSS REFERENCE TO RELATED APPLICATION(S)

This application claims priority to and benefits of Korean Patent Application No. 10-2023-0062015 under 35 U.S.C. § 119, filed on May 12, 2023, in the Korean Intellectual Property Office (KIPO), the entire contents of which are incorporated herein by reference.

### BACKGROUND

### 1. Technical Field

Embodiments relate to a display device.

### 2. Description of the Related Art

Recently, as interest in information displays is increased, research and development of display devices have been continuously conducted.

### SUMMARY

The disclosure provides a display device including a boost capacitor having a large charge capacity in a limited space.

According to an embodiment, a display device may include a first electrode of a boost capacitor, disposed on a base layer, a second electrode of the boost capacitor, disposed on the first electrode of the boost capacitor, a gate electrode of a driving transistor, disposed on the base layer, and a connection electrode electrically connecting the gate electrode of the driving transistor and the second electrode of the boost capacitor to each other. The second electrode of the boost capacitor may be disposed between the first electrode of the boost capacitor and the connection electrode, and the gate electrode of the driving transistor and the first electrode of the boost capacitor may be disposed in a same layer.

The display device may further include a first insulating layer disposed between the base layer, and the gate electrode of the driving transistor and the first electrode of the boost capacitor.

The display device may further include a semiconductor layer disposed between the base layer and the first insulating layer.

The display device may further include a second insulating layer disposed between the first electrode of the boost capacitor and the second electrode of the boost capacitor.

The display device may further include a third insulating layer disposed between the second electrode of the boost capacitor and the connection electrode.

The connection electrode may contact the second electrode of the boost capacitor through a contact hole penetrating the third insulating layer.

The connection electrode may contact the gate electrode of the driving transistor through a contact hole penetrating the second insulating layer and the third insulating layer.

The display device may further include a fourth insulating layer disposed between the third insulating layer and the connection electrode.

The connection electrode may contact the second electrode of the boost capacitor through a contact hole penetrating the third insulating layer and the fourth insulating layer.

The connection electrode may contact the gate electrode of the driving transistor through a contact hole penetrating the second insulating layer, the third insulating layer, and the fourth insulating layer.

According to an embodiment, a display device may include a gate electrode of a driving transistor and a first electrode of a boost capacitor, each disposed on a semiconductor layer, a second electrode of the boost capacitor, disposed on the first electrode of the boost capacitor, and a connection electrode disposed on the gate electrode of the driving transistor. The connection electrode may be electrically connected to the gate electrode of the driving transistor and the second electrode of the boost capacitor.

The gate electrode of the driving transistor and the first electrode of the boost capacitor may be disposed in a same layer.

The display device may further include a first insulating layer disposed between the semiconductor layer, and the gate electrode of the driving transistor and the first electrode of the boost capacitor.

The display device may further include a second insulating layer disposed between the first electrode of the boost capacitor and the second electrode of the boost capacitor.

The display device may further include a third insulating layer disposed between the second electrode of the boost capacitor and the connection electrode.

The connection electrode may contact the second electrode of the boost capacitor through a contact hole penetrating the third insulating layer.

The connection electrode may contact the gate electrode of the driving transistor through a contact hole penetrating the second insulating layer and the third insulating layer.

The display device may further include a fourth insulating layer disposed between the third insulating layer and the connection electrode.

The connection electrode may contact the second electrode of the boost capacitor through a contact hole penetrating the third insulating layer and the fourth insulating layer.

The connection electrode may contact the gate electrode of the driving transistor through a contact hole penetrating the second insulating layer, the third insulating layer, and the fourth insulating layer.

### BRIEF DESCRIPTION OF THE DRAWINGS

The embodiments will now be described more fully hereinafter with reference to the accompanying drawings, however, the disclosure may be embodied in different forms and should not be construed as limited to the embodiments set forth herein. Rather, these embodiments are provided so that this disclosure will be more thorough and complete, and will fully convey the scope of the disclosure to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the disclosure.

FIG. 2 is a schematic diagram of an equivalent circuit illustrating a pixel in accordance with an embodiment of the disclosure.

FIG. 3 is a schematic plan view illustrating a layout of a pixel circuit of the pixel of FIG. 2.

FIG. 4 is a schematic plan view illustrating a first conductive layer of FIG. 3.

FIG. 5 is a schematic plan view illustrating a first semiconductor layer of FIG. 3.

FIG. 6 is a schematic plan view illustrating a second conductive layer of FIG. 3.

FIG. 7 is a schematic plan view illustrating a third conductive layer of FIG. 3.

FIG. 8 is a schematic plan view illustrating a second semiconductor layer of FIG. 3.

FIG. 9 is a schematic plan view illustrating a fourth conductive layer of FIG. 3.

FIG. 10 is a schematic plan view illustrating a fifth conductive layer of FIG. 3.

FIG. 11 is a schematic plan view illustrating a sixth conductive layer of FIG. 3.

FIG. 12 is a schematic cross-sectional view illustrating a pixel.

FIGS. 13 and 14 are schematic cross-sectional views taken along line A-A′ of FIG. 3.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms. The embodiments are provided by way of example only so that a person of ordinary skilled in the art can fully understand the features in the disclosure and the scope thereof. Therefore, the disclosure can be defined by the scope of the appended claims.

The terminology used herein is for the purpose of describing particular embodiments and is not intended to be limiting. As used herein, the singular forms, “a,” “an,” and “the” are intended to include the plural forms as well, unless the context clearly indicates otherwise. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

It will be understood that when an element such as a layer, film, region, or substrate is referred to as being “on” or “above” another element, it can be directly on the other element or intervening element(s) may also be present. In contrast, when an element is referred to as being “directly on” another element, no intervening elements are present.

The terminology used herein is for the purpose of describing particular embodiments only and is not construed as limiting the disclosure. As used herein, the singular forms are intended to include the plural forms as well, unless the context clearly indicates otherwise. The terms “comprises/includes/has” and/or “comprising/including/having,” when used in this specification, specify the presence of mentioned component, step, operation and/or element, but do not exclude the presence or addition of one or more other components, steps, operations, and/or elements.

When described as that any element is “connected,” “coupled,” or “accessed” to another element, it should be understood that it is possible that still another element may “connected,” “coupled,” or “accessed” between the two elements as well as that the two elements are directly “connected,” “coupled,” or “accessed” to each other. When, however, an element or layer is referred to as being “directly connected to,” “directly coupled to,” or “directly accessed,” another element or layer, there are no intervening elements or layers present. To this end, the term “connected” may refer to physical, electrical, and/or fluid connection, with or without intervening elements. Further, the X-axis direction, the Y-axis direction, and the Z-axis direction are not limited to three axes of a rectangular coordinate system, such as the x, y, and z axes directions, and may be interpreted in a broader sense. For example, the X-axis direction, the Y-axis direction, and the Z-axis direction may be perpendicular to one another, or may represent different directions that are not perpendicular to one another.

The term “on” that is used to designate that an element or layer is on another element or layer includes both a case where an element or layer is located directly on another element or layer, and a case where an element or layer is located on another element or layer via still another element layer. In contrast, when an element is referred to as being “directly on” another element, no intervening elements are present. Like reference numerals generally denote like elements throughout the specification.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

For the purposes of this disclosure, the phrase “at least one of A and B” may be construed as A only, B only, or any combination of A and B. “At least one of X, Y, and Z” and “at least one selected from the group consisting of X, Y, and Z” may be construed as X only, Y only, Z only, or any combination of two or more of X, Y, and Z. Also, “at least two of X, Y, and Z” may be construed as two or more of X, Y, and Z such as both X and Y, both X and Z, both Y and Z, both X, Y, and Z.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Spatially relative terms, such as “under,” “lower,” “above,” “upper,” “higher,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some example embodiments may be physically separated into two or more interacting and discrete blocks, units, parts, and/or modules without departing from the scope of the disclosure. Further, the blocks, units, parts, and/or modules of some example embodiments may be physically combined into more complex blocks, units, parts, and/or modules without departing from the scope of the disclosure.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction (X-axis direction) and a second direction (Y-axis direction). A normal direction of the display surface, i.e., a thickness direction of the display device or a display panel PNL, may indicate a third direction (Z-axis direction). In this specification, an expression of “when viewed from the top or in a plan view” may represent a case when viewed in the third direction. Hereinafter, a front surface (or a top surface) and a rear surface (or a bottom surface) of each of layers or units may be distinguished by the third direction. However, directions indicated by the first to third directions may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in more detail with reference to the accompanying drawings.

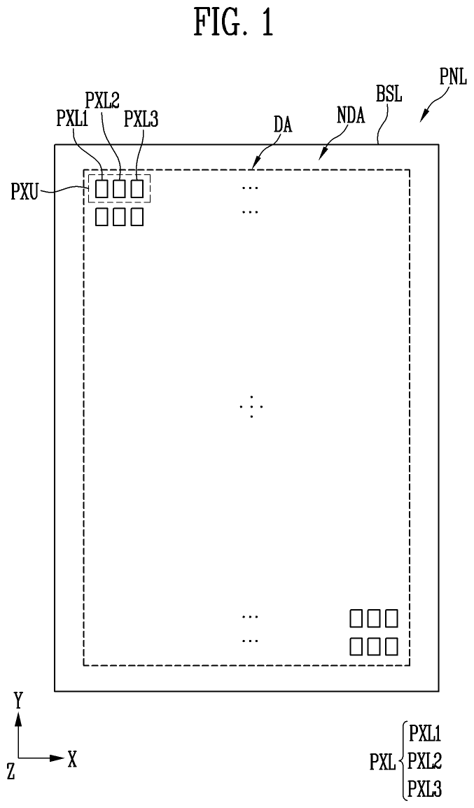

FIG. 1 is a schematic plan view illustrating a display device in accordance with an embodiment of the disclosure.

In FIG. 1, a display device, particularly, a display panel PNL provided in the display device will be illustrated as an embodiment of an electronic device.

In FIG. 1, for convenience of description, a structure of the display panel PNL will be illustrated based on a display area DA. However, in an embodiment, at least one driving circuit (e.g., at least one of a scan driver and a data driver), lines, and/or pads, which are not shown, may be further disposed in the display panel PNL.

Referring to FIG. 1, the display panel PNL and a base layer BSL for forming the display panel PNL may include the display area DA for displaying an image and a non-display area NDA other than the display area DA. For example, the non-display area NDA may be disposed adjacent to the display area DA. For example, the non-display area NDA may surround at least a portion of the display area DA. The display area DA may constitute a screen on which the image is displayed, and the non-display area NDA may be a remaining area other than the display area DA.

A pixel unit PXU may be disposed in the display area DA. The pixel unit PXU may include a first pixel PXL1, a second pixel PXL2, and/or a third pixel PXL3. Hereinafter, in case that at least one of a first pixel PXL1, a second pixel PXL2, and a third pixel PXL3 is arbitrarily designated or in case that at least two of the first pixel PXL1, the second pixel PXL2, and the third pixel PXL3 are inclusively designated, each of the first, second, and third pixels PXL1, PXL2, and PXL3 or the first, second, and third pixels PXL1, PXL2, and PXL3 will be referred to as a “pixel PXL” or “pixels PXL.”

In an embodiment, the pixels PXL may be regularly arranged according to a strip arrangement structure, a PenTile™ arrangement structure, or the like. However, the arrangement structure of the pixels PXL is not limited thereto, and the pixels PXL may be arranged in the display area DA in various structures and/or various manners.

In an embodiment, at least two of pixels PXL emitting lights of different colors may be arranged in the display area DA. In an embodiment, first pixels PXL1 emitting light of a first color, second pixels PXL2 emitting light of a second color, and third pixels PXL3 emitting light of a third color may be arranged in the display area DA. At least one first pixel PXL1, at least one second pixel PXL2, and at least one third pixel PXL3, which are disposed adjacent to each other, may constitute one pixel unit PXU that emits lights of various colors. For example, each of the first to third pixels PXL1, PXL2, and PXL3 may be a pixel emitting light of a color (e.g., a predetermined or selectable color). In an embodiment, the first pixel PXL1 may be a red pixel emitting light of red, the second pixel PXL2 may be a green pixel emitting light of green, and the third pixel PXL3 may be a blue pixel emitting light of blue. However, the disclosure is not limited thereto.

In an embodiment, the first pixel PXL1, the second pixel PXL2, and the third pixel PXL3 may include light emitting elements emitting light of the same color, and may include color filters of different colors, which are disposed above the respective light emitting elements, to respectively emit lights of the first color, the second color, and the third color. In another embodiment, the first pixel PXL1, the second pixel PXL2, and the third pixel PXL3 may include, as light sources, a light emitting element of the first color, a light emitting element of the second color, and a light emitting element of the third color, and may emit lights of the first color, the second color, and the third color, respectively. However, the color, kind, and/or number of pixels PXL constituting each pixel unit PXU are not particularly limited thereto. For example, the color of light emitted from each pixel PXL may be variously changed.

In an embodiment, each pixel PXL may be configured as an active pixel. However, the kind, structure, and/or driving method of pixels PXL applicable to the display device are not particularly limited thereto. For example, each pixel PXL may be configured as a pixel of a passive or active light emitting display device using various structures and/or driving methods.

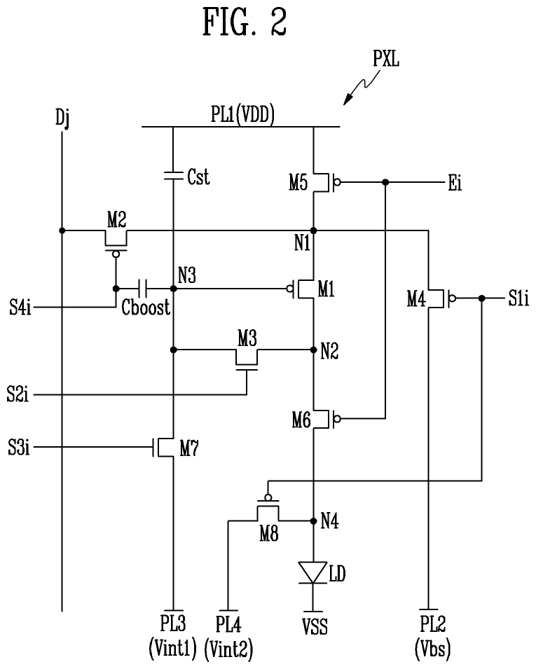

FIG. 2 is a schematic diagram of an equivalent circuit illustrating a pixel in accordance with an embodiment of the disclosure.

In FIG. 2, for convenience of illustration, a pixel PXL which is located on an ith horizontal line (or ith pixel row) and is electrically connected to a jth data line Dj will be illustrated (i and j are positive integers).

Referring to FIG. 2, the pixel PXL may include a light emitting element LD, first to eighth transistors M1, M2, M3, M4, M5, M6, M7, and M8, a storage capacitor Cst, and a boost capacitor Cboost.

A first electrode (or anode electrode or cathode electrode) of the light emitting element LD may be electrically connected to the sixth transistor M6, and a second electrode (cathode electrode or anode electrode) of the light emitting element LD may be electrically connected to an electrode supplying a second driving power source VSS. The light emitting element LD may generate light with a luminance (e.g., a predetermined or selectable luminance) corresponding to an amount of current supplied from the first transistor M1.

In an embodiment, the light emitting element LD may be an organic light emitting diode including an organic light emitting layer. In another embodiment, the light emitting element LD may be an inorganic light emitting element including an inorganic material. In another embodiment, the light emitting element LD may be a light emitting element including a combination of an inorganic material and an organic material. In another embodiment, the light emitting element LD may have a form in which multiple inorganic light emitting elements are electrically connected in parallel and/or series between the second driving power source VSS and the sixth transistor M6.

A first electrode of the first transistor M1 (or driving transistor) may be electrically connected to a first node N1, and a second electrode of the first transistor M1 may be electrically connected to a second node N2. A gate electrode of the first transistor M1 may be electrically connected to a third node N3. The first transistor M1 may control an amount of current flowing from a first driving power source VDD to the second driving power source VSS via the light emitting element LD, corresponding to a voltage of the third node N3. For example, the first driving power source VDD may be set to a voltage higher than a voltage of the second driving power source VSS.

The second transistor M2 may be electrically connected between a jth data line Dj (hereinafter, referred to as a data line) and the first node N1. A gate electrode of the second transistor M2 may be electrically connected to an ith fourth scan line S4i (hereinafter, referred to as a fourth scan line). The second transistor M2 may be turned on in case that a fourth scan signal is supplied to the fourth scan line S4i, to electrically connect the data line Dj and the first node N1 to each other.

The third transistor M3 may be electrically connected between the second electrode of the first transistor M1 (i.e., the second node N2) and the third node N3. A gate electrode of the third transistor M3 may be electrically connected to an ith second scan line S2i (hereinafter, referred to as a second scan line). The third transistor M3 may be turned on in case that a second scan signal is supplied to the second scan line S2i, to electrically connect the second electrode of the first transistor M1 and the third node N3 to each other. For example, a timing at which the second electrode (e.g., a drain electrode) of the first transistor M1 and the gate electrode of the first transistor M1 are electrically connected to each other may be controlled by the second scan signal. In case that the third transistor M3 is turned on, the first transistor M1 may be electrically connected in a diode form.

The fourth transistor M4 may be electrically connected between the first node N1 and a second power line PL2 providing a voltage of a first power source Vbs. The fourth transistor M4 may be turned on in response to a first scan signal supplied to an ith first scan line S1i (hereinafter, referred to as a first scan line), and supply the voltage of the first power source Vbs to the first node N1. A timing at which the voltage of the first power source Vbs is supplied to the first node N1 may be controlled by the first scan signal.

In an embodiment, the voltage of the first power source Vbs may be a level similar to a level of a data voltage of a black grayscale. For example, the voltage of the first power source Vbs may be in a range of about 5 V to about 7 V. In another embodiment, the voltage of the first power source Vbs may be higher than the voltage of the first driving power source VDD and be lower than a voltage corresponding to a high level of scan signals.

Accordingly, as the fourth transistor M4 is turned on, a high voltage (e.g., a predetermined or selectable high voltage) may be applied to the first electrode (e.g., a source electrode) of the first transistor M1. In case that the third transistor M3 is in a state in which the third transistor M3 is turned off, the first transistor M1 may have an on-bias state (i.e., a state in which the first transistor M1 can be turned on) (i.e., be on-biased).

The fifth transistor M5 may be electrically connected between a first power line PL1 providing the first driving power source VDD and the first node N1. A gate electrode of the fifth transistor M5 may be electrically connected to an ith emission control line Ei (hereinafter, referred to as an emission control line). The fifth transistor M5 may be turned off in case that an emission control signal is supplied to the emission control line Ei, and be turned on in other cases.

The sixth transistor M6 may be electrically connected between the second electrode of the first transistor M1 (i.e., the second node N2) and the first electrode of the light emitting element LD (i.e., a fourth node N4). A gate electrode of the sixth transistor M6 may be electrically connected to the emission control line Ei. The sixth transistor M6 may be controlled substantially identical to the fifth transistor M5.

The seventh transistor M7 may be electrically connected between the third node N3 and a third power line PL3 providing a first initialization power source Vint1. A gate electrode of the seventh transistor M7 may be electrically connected to an ith third scan line S3i (hereinafter, referred to as a third scan line).

The seventh transistor M7 may be turned on in case that a third scan signal is supplied to the third scan line S3i, to supply a voltage of the first initialization power source Vint1 to the third node N3. The voltage of the first initialization power source Vint1 may be set to a voltage lower than a minimum level of a data signal supplied to the data line Dj. Accordingly, as the seventh transistor M7 is turned on, a gate voltage of the first transistor M1 may be initialized to the voltage of the first initialization power source Vint1.

The eighth transistor M8 may be electrically connected between the first electrode of the light emitting element LD (i.e., the fourth node N4) and a fourth power line PL4 providing a third power source Vint2 (hereinafter, referred to as a second initialization power source). In an embodiment, a gate electrode of the eighth transistor M8 may be electrically connected to the first scan line S1i.

The eighth transistor M8 may be turned on in case that the first scan signal is supplied to the first scan line S1i, to supply a voltage of the second initialization power source Vint2 to the first electrode of the light emitting element LD.

In case that the voltage of the second initialization power source Vint2 is supplied to the first electrode of the light emitting element LD, a parasitic capacitor of the light emitting element LD may be discharged. As a residual voltage charged in the parasitic capacitor is charged (removed), unintended minute light emission may be prevented. A black expression ability of the pixel PXL may be improved.

The first initialization power source Vint1 and the second initialization power source Vint2 may generate different voltages. In an embodiment, a voltage for initializing the third node N3 and a voltage for initializing the fourth node N4 may be set different from each other. However, the disclosure is not necessarily limited thereto, and in another embodiment, the voltage of the first initialization power source Vint1 and the voltage of the second initialization power source Vint2 may be substantially the same.

The storage capacitor Cst may be electrically connected between the first power line PL1 and the third node N3. The storage capacitor Cst may store a voltage applied to the third node N3.

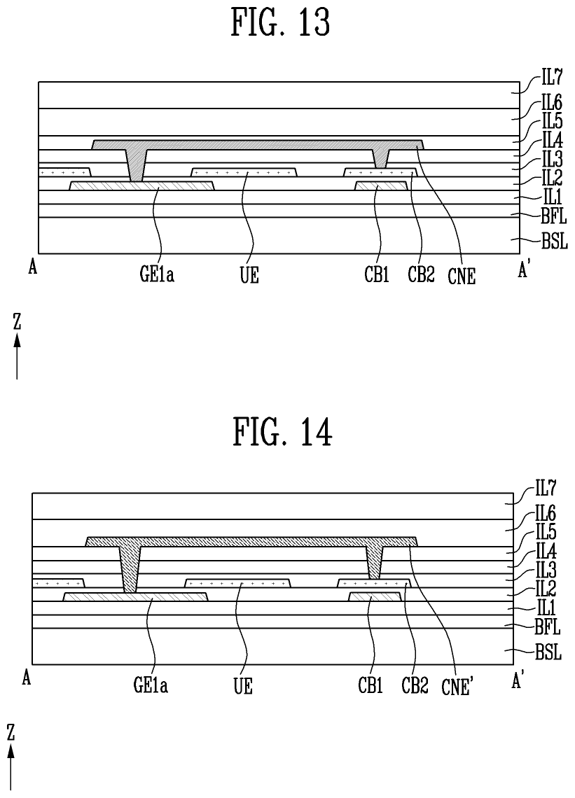

The boost capacitor Cboost may be electrically connected between the fourth scan line S4i and the gate electrode of the first transistor M1. The boost capacitor Cboost may be electrically connected to the fourth scan line S4i, the voltage of the gate electrode (see, e.g., GE1a of FIG. 13) of the first transistor M1 may be lowered by the fourth scan signal supplied to the fourth scan line S4i, and a turn-on characteristic of the first transistor M1 may be improved. The boost capacitor Cboost will be described in detail below with reference to FIGS. 13 and 14.

In an embodiment, the first transistor M1, the second transistor M2, the fourth transistor M4, the fifth transistor M5, the sixth transistor M6, and the eighth transistor M8 may be formed with a poly-silicon semiconductor transistor. For example, the first transistor M1, the second transistor M2, the fourth transistor M4, the fifth transistor M5, the sixth transistor M6, and the eighth transistor M8 may include a poly-silicon semiconductor layer formed as an active layer (channel) through a low temperature poly-silicon (LTPS) process or the like.

The first transistor M1, the second transistor M2, the fourth transistor M4, the fifth transistor M5, the sixth transistor M6, and the eighth transistor M8 may be a P-type transistor (e.g., a PMOS transistor). Accordingly, a gate-on voltage at which the first transistor M1, the second transistor M2, the fourth transistor M4, the fifth transistor M5, the sixth transistor M6, and the eighth transistor M8 are turned on may have a logic low level. Since the poly-silicon semiconductor transistor has an advantage of high response speed, the poly-silicon semiconductor transistor may be applied to a switching element which requires fast switching.

The third transistor M3 and the seventh transistor M7 may be formed with an oxide semiconductor transistor. For example, the third transistor M3 and the seventh transistor M7 may be an N-type oxide semiconductor transistor (e.g., an NMOS transistor), and include an oxide semiconductor layer as an active layer. Accordingly, a gate-on voltage at which the third transistor M3 and the seventh transistor M7 are turned on may have a logic high level.

The oxide semiconductor transistor may be formed through a low temperature process or the like, and have a charge mobility lower than a charge mobility of the poly-silicon semiconductor transistor. For example, the oxide semiconductor transistor may have an excellent off-current characteristic. In case that the third transistor M3 and the seventh transistor M7 are an oxide semiconductor transistor, leakage current from the third node N3 according to low frequency driving may be minimized, and accordingly, display quality may be improved.

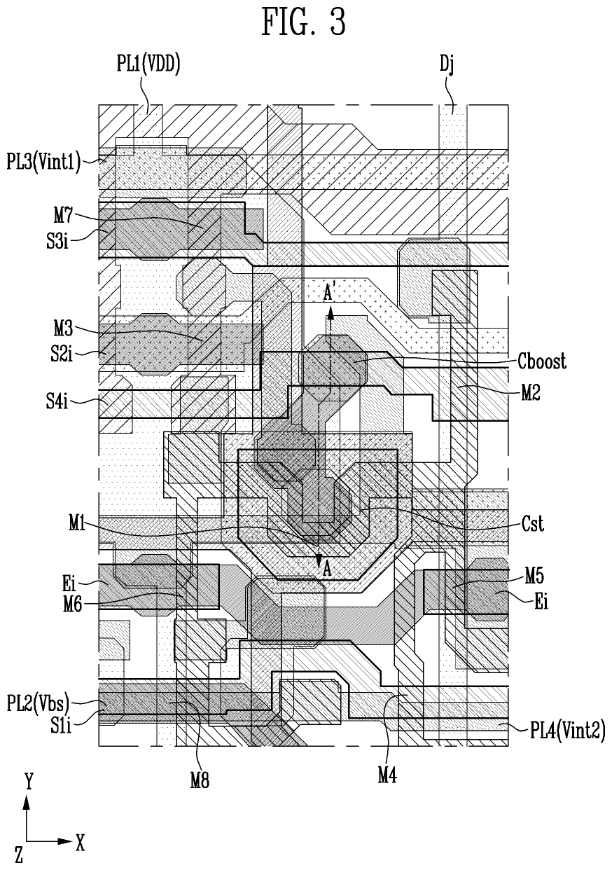

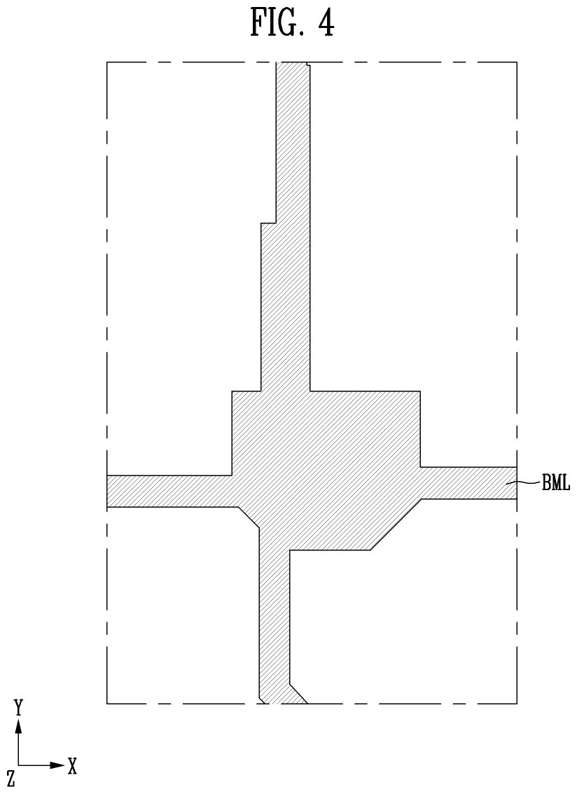

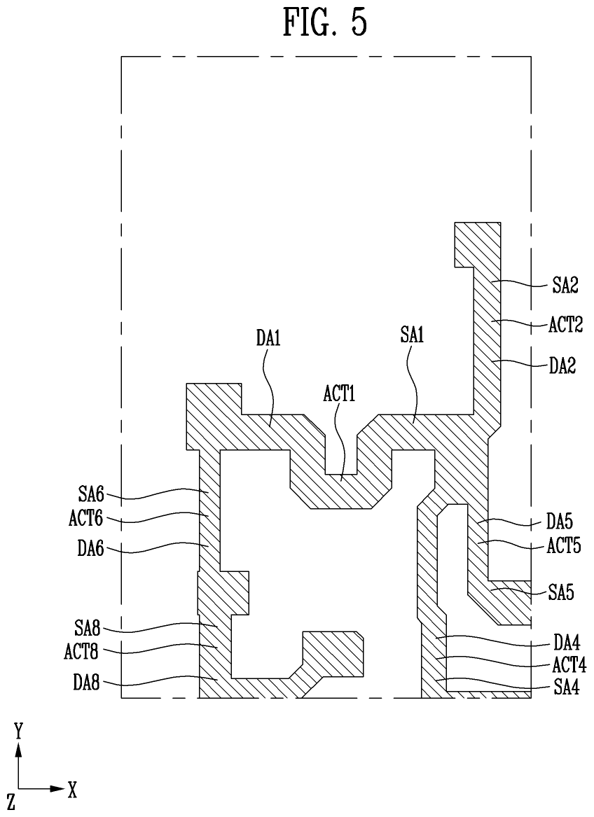

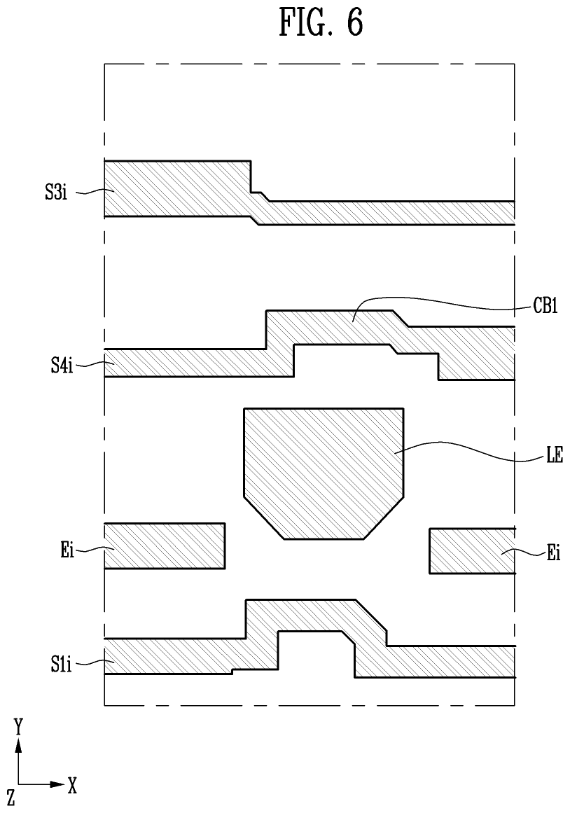

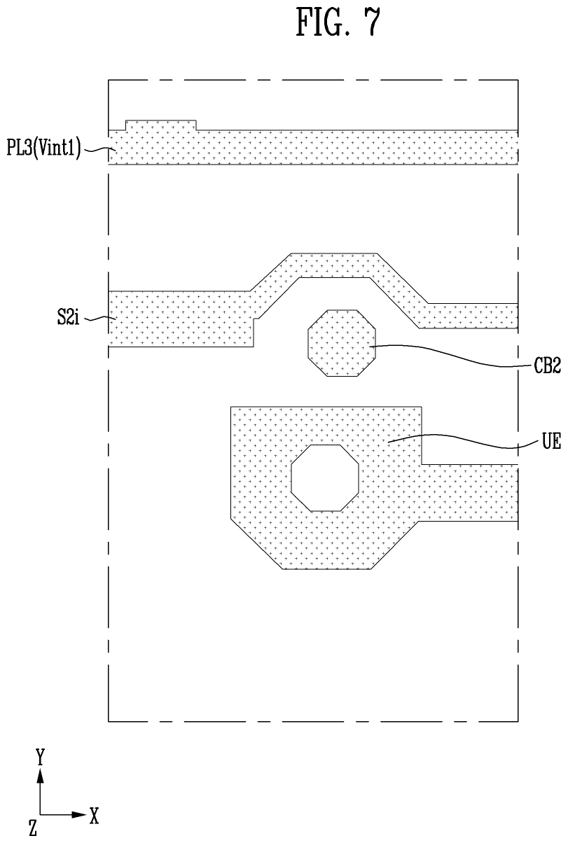

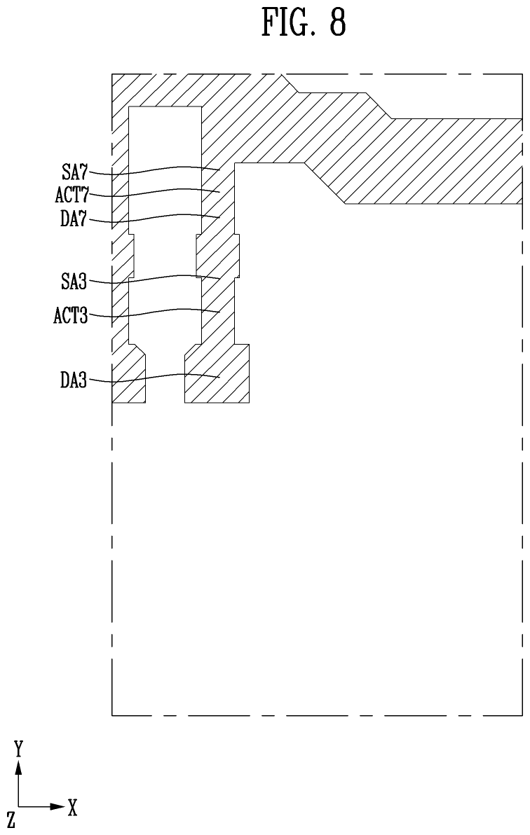

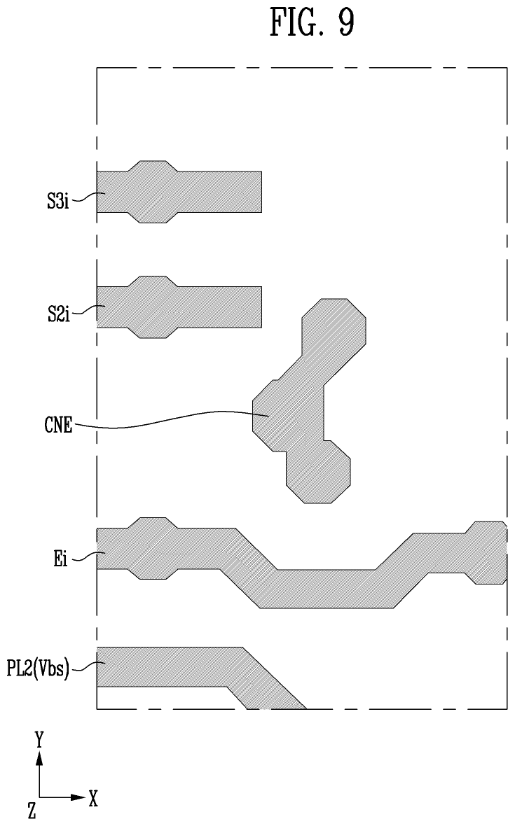

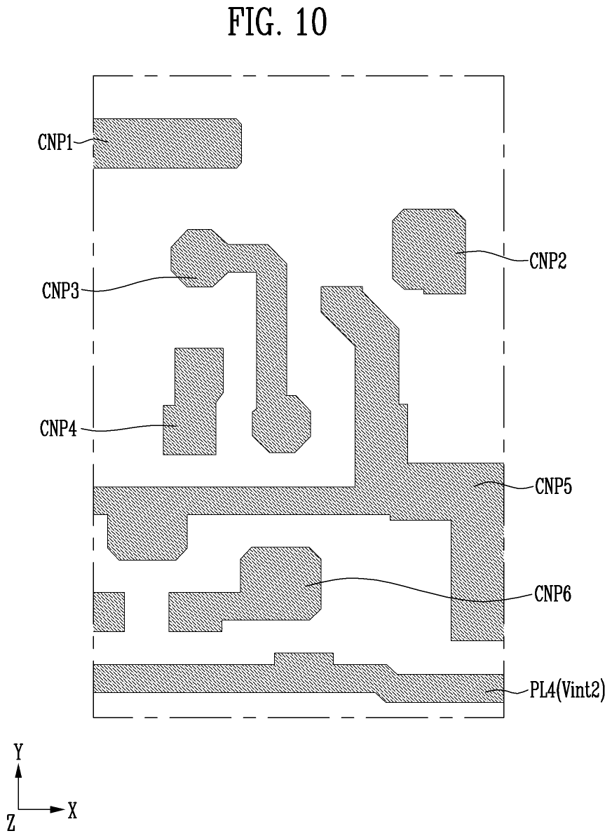

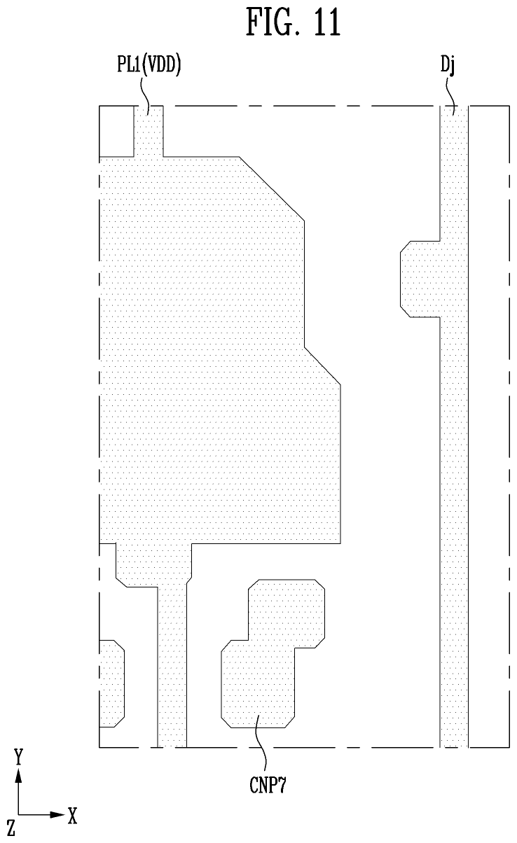

FIG. 3 is a schematic plan view illustrating a layout of the pixel circuit of the pixel of FIG. 2. FIG. 4 is a schematic plan view illustrating a first conductive layer of FIG. 3. FIG. 5 is a schematic plan view illustrating a first semiconductor layer of FIG. 3. FIG. 6 is a schematic plan view illustrating a second conductive layer of FIG. 3. FIG. 7 is a schematic plan view illustrating a third conductive layer of FIG. 3. FIG. 8 is a schematic plan view illustrating a second semiconductor layer of FIG. 3. FIG. 9 is a schematic plan view illustrating a fourth conductive layer of FIG. 3. FIG. 10 is a schematic plan view illustrating a fifth conductive layer of FIG. 3. FIG. 11 is a schematic plan view illustrating a sixth conductive layer of FIG. 3.

In FIG. 3, for convenience of description, FIG. 3 illustrates that a backplane structure includes the pixel circuit, and the light emitting element (see, e.g., LD of FIG. 2) is omitted. Referring to FIGS. 3 to 11, the backplane structure may include the first to eighth transistors M1, M2, M3, M4, M5, M6, M7, and M8, the storage capacitor Cst, and the boost capacitor Cboost, which constitute the pixel circuit, and include various signal lines electrically connected to the first to the eighth transistors M1, M2, M3, M4, M5, M6, M7, and M8, the storage capacitor Cst, and the boost capacitor Cboost, which constitute the pixel circuit.

Referring to FIGS. 3 and 4, the first conductive layer may include a bottom metal layer BML. The bottom metal layer BML may overlap a first active area (see. e.g., ACT1 of FIG. 5) of the first transistor M1 in a plan view. The bottom metal layer BML may include a metal such as copper (Cu), molybdenum (Mo), aluminum (Al), titanium (Ti), the like, or a metal alloy, and have a single layer or multi-layers.

Referring to FIGS. 3 and 5, the first semiconductor layer may include active regions ACT1, ACT2, ACT4, ACT5, ACT6, and ACT8, source regions SA1, SA2, SA4, SA5, SA6, and SA8, and drain regions DA1, DA2, DA4, DA5, DA6, and DA8. The first semiconductor layer may be a poly-silicon semiconductor layer. For example, the first semiconductor layer may be formed through a low temperature poly-silicon (LTPS) process or the like.

Portions overlapping the second conductive layer in the first semiconductor layer in a plan view may be respectively defined as first, second, fourth, fifth, sixth, and eighth active regions ACT1, ACT2, ACT4, ACT5, ACT6, and ACT8. The first, second, fourth, fifth, sixth, and eighth active regions ACT1, ACT2, ACT4, ACT5, ACT6, and ACT8 may respectively correspond to the first, second, fourth, fifth, sixth, and eighth transistors M1, M2, M4, M5, M6, and M8.

First, second, fourth, fifth, sixth, and eighth source regions SA1, SA2, SA4, SA5, SA6, and SA8 may respectively correspond to the first, second, fourth, fifth, sixth, and eighth transistors M1, M2, M4, M5, M6, and M8. First, second, fourth, fifth, sixth, and eighth drain regions DA1, DA2, DA4, DA5, DA6, and DA8 may respectively correspond to the first, second, fourth, fifth, sixth, and eighth transistors M1, M2, M4, M5, M6, and M8.

An end of the first active region ACT1 may be electrically connected to the first source region SA1, and another end of the first active region ACT1 may be electrically connected to the first drain region DA1. Relationships between other active regions ACT2, ACT4, ACT5, ACT6, and ACT8 and other source regions SA2, SA4, SA5, SA6, and SA8 and other drain regions DA2, DA4, DA5, DA6, and DA8 may be similar to the relationship between the first active region ACT1, the first source region SA1, and the first drain region DA1.

The first active region ACT1 may have a shape extending in a first direction (X-axis direction), and have a shape bent multiple times. The first active region ACT1 may be formed long, and a channel region of the first transistor M1 may be formed long. Accordingly, a driving range of a gate voltage applied to the first transistor M1 may be widened. In an embodiment, the first direction (X-axis direction) may be a direction substantially parallel to a horizontal direction or a pixel row.

Referring to FIGS. 3 and 6, the second conductive layer may include a third scan line S3i, a fourth scan line S4i, a first electrode CB1 of the boost capacitor Cboost, a lower electrode LE of the storage capacitor Cst, an emission control line Ei, and a first scan line S1i.

The third scan line S3i, the fourth scan line S4i, the emission control line Ei, and/or the first scan line S1i may extend in the first direction (X-axis direction). The fourth scan line S4i and the first electrode CB1 of the boost capacitor Cboost may be integrally formed, but the disclosure is not limited thereto.

In an embodiment, portions overlapping the first semiconductor layer in the second conductive layer in a plan view may be respectively gate electrodes of the first, second, fourth, fifth, sixth, and eighth transistors M1, M2, M4, M5, M6, and M8.

The third scan line S3i, the fourth scan line S4i, the first electrode CB1 of the boost capacitor Cboost, the lower electrode LE of the storage capacitor (see, e.g., Cst of FIG. 2), the emission control line Ei, and the first scan line S1i may include a same material in a same layer through a same process.

Referring to FIGS. 3 and 7, the third conductive layer may include a third power line PL3, a second scan line S2i, a second electrode CB2 of the boost capacitor Cboost, and an upper electrode UE of the storage capacitor (see, e.g., Cst of FIG. 2).

The third power line PL3 and the second scan line S2i may extend in the first direction (X-axis direction).

The second electrode CB2 of the boost capacitor Cboost may overlap the first electrode (see, e.g., CB1 of FIG. 6) of the boost capacitor Cboost in a plan view. Therefore, the boost capacitor Cboost may be formed by the first electrode (see, e.g., CB1 of FIG. 6) and the second electrode CB2 with an insulating layer interposed between the first electrode (see, e.g., CB1 of FIG. 6) and the second electrode CB2.

The upper electrode UE of the storage capacitor (see, e.g., Cst of FIG. 2) may overlap the lower electrode (see, e.g., LE of FIG. 6) of the storage capacitor Cst in a plan view. Therefore, the storage capacitor (see, e.g., Cst of FIG. 2) may be formed by the upper electrode UE and the lower electrode (see, e.g., LE of FIG. 6) with an insulating layer interposed between the upper electrode UE and the lower electrode (see, e.g., LE of FIG. 6). In an embodiment, the upper electrode UE of the storage capacitor (see, e.g., Cst of FIG. 2) may include an opening.

The third power line PL3, the second scan line S2i, the second electrode CB2 of the boost capacitor Cboost, and the upper electrode UE of the storage capacitor (see, e.g., Cst of FIG. 2) may be formed of a same material in a same layer through a same process.

Referring to FIGS. 3 and 8, the second semiconductor layer may include third and seventh active regions ACT3 and ACT7, third and seventh source regions SA3 and SA7, and third and seventh drain region DA3 and DA7. The second semiconductor layer may include an oxide semiconductor layer.

Portions overlapping the fourth conductive layer in the second semiconductor layer in a plan view may be respectively defined as the third and seventh active regions ACT3 and ACT7. The third and seventh active regions ACT3 and ACT7 may respectively correspond to the third and seventh transistors M3 and M7.

The third and seventh source regions SA3 and SA7 may respectively correspond to the third and seventh transistors M3 and M7. The third and seventh drain regions DA3 and DA7 may respectively correspond to the third and seventh transistors M3 and M7.

An end of the third active region ACT3 may be electrically connected to the third source region SA3, and another end of the third active region ACT3 may be electrically connected to the third drain region DA3. An end of the seventh active region ACT7 may be electrically connected to the seventh source region SA7, and another end of the seventh active region ACT7 may be electrically connected to the seventh drain region DA7.

Referring to FIGS. 3 and 9, the fourth conductive layer may include the third scan line S3i, the second scan line S2i, a connection electrode CNE, the emission control line Ei, and a second power line PL2.

The third scan line S3i, the second scan line S2i, the emission control line Ei, and/or the second power line PL2 may extend in the first direction (X-axis direction).

In an embodiment, portions overlapping the second semiconductor layer in the fourth conductive layer in a plan view may be respectively gate electrodes of the third transistor M3 and the seventh transistor M7.

The connection electrode CNE may be electrically connected to the second conductive layer (e.g., a first gate electrode (see, e.g., GE1a of FIG. 13) of the first transistor M1) and the third conductive layer (e.g., the second electrode (see, e.g., CB2 of FIG. 7) of the boost capacitor Cboost). The connection electrode CNE may be electrically connected to the first gate electrode (see, e.g., GE1a of FIG. 13) of the first transistor M1 disposed under the connection electrode CNE through the opening of the upper electrode (see, e.g., UE of FIG. 7) of the storage capacitor (see, e.g., Cst of FIG. 2).

The third scan line S3i, the second scan line S2i, the connection electrode CNE, the emission control line Ei, and the second power line PL2 may be formed of a same material in a same layer through a same process.

Referring to FIGS. 3 and 10, the fifth conductive layer may include first to sixth conductive patterns CNP1, CNP2, CNP3, CNP4, CNP5, and CNP6, and a fourth power line PL4.

The first conductive pattern CNP1 may electrically connect the seventh transistor M7 and the third power line PL3 to each other. An end of the first conductive pattern CNP1 may be electrically connected to the seventh source region SA7 of the second semiconductor layer, and another end of the first conductive pattern CNP1 may be electrically connected to the third power line PL3. Accordingly, the voltage of the first initialization power source Vint1 may be provided to the seventh transistor M7.

The second conductive pattern CNP2 may electrically connect a data line Dj and the second transistor M2 to each other. For example, the second conductive pattern CNP2 may be electrically connected to the data line Dj of the sixth conductive layer which will be described below, and be electrically connected to the second source region SA2 of the first semiconductor layer.

The third conductive pattern CNP3 may electrically connect the lower electrode (see, e.g., LE of FIG. 6) of the storage capacitor (see, e.g., Cst of FIG. 2) and the seventh transistor M7 to each other. In an embodiment, an end of the third conductive pattern CNP3 may be electrically connected to the lower electrode (see, e.g., LE of FIG. 6) through the connection electrode CNE of the fourth conductive layer, and another end of the third conductive pattern CNP3 may be electrically connected to the seventh drain region (see, e.g., DA7 of FIG. 8) of the second semiconductor layer.

The fourth conductive pattern CNP4 may electrically connect the third transistor M3 and the first transistor M1 to each other. In an embodiment, an end of the fourth conductive pattern CNP4 may be electrically connected to the first drain region (see, e.g., DA1 of FIG. 5) of the first semiconductor layer, and another end of the fourth conductive pattern CNP4 may be electrically connected to the third drain region (see, e.g., DA3 of FIG. 8) of the second semiconductor layer.

The fifth conductive pattern CNP5 may be electrically connected to a first power line PL1 of the sixth conductive layer which will be described below. Also, the fifth conductive pattern CNP5 may be electrically connected to the upper electrode (see, e.g., UE of FIG. 7) of the storage capacitor (see, e.g., Cst of FIG. 2) of the third conductive layer and/or the fifth source region (see, e.g., SA5 of FIG. 5) of the first semiconductor layer. Accordingly, the voltage of the first driving power source VDD may be provided to the fifth transistor M5 through the fifth conductive pattern CNP5.

The sixth conductive pattern CNP6 may electrically connect the sixth transistor M6 and a light emitting element (see, e.g., LD of FIG. 2) to each other. In an embodiment, an end of the fifth conductive pattern CNP5 may be electrically connected to the sixth drain region (see, e.g., DA6 of FIG. 6) of the first semiconductor layer. Another end of the fifth conductive pattern CNP5 may be electrically connected to a seventh conductive pattern CNP7 of the sixth conductive layer which will be described below. The seventh conductive pattern CNP7 may be electrically connected to a first electrode of the light emitting element (see, e.g., LD of FIG. 2) disposed on the seventh conductive pattern CNP7.

The fourth power line PL4 may be electrically connected to the eighth drain region (see, e.g., DA8 of FIG. 6) of the first semiconductor layer. Therefore, the voltage of the second initialization power source Vint2 may be provided to the eighth transistor M8. The fourth power line PL4 may extend in the first direction (X-axis direction).

The first to sixth conductive patterns CNP1, CNP2, CNP3, CNP4, CNP5, and CNP6 and the fourth power line PL4 may be formed of a same material in a same layer through a same process.

Referring to FIGS. 3 and 11, the sixth conductive layer may include the first power line PL1, the data line Dj, and the seventh conductive pattern CNP7.

The first power line PL1 may extend in a second direction (Y-axis direction). The first power line PL1 may be electrically connected to the fifth conductive pattern (see, e.g., CNP5 of FIG. 10) of the fifth conductive layer. Accordingly, the voltage of the first driving power source VDD may be provided to the pixel PXL.

The data line Dj may extend in the second direction (Y-axis direction), and provide a data signal. The data line Dj may be electrically connected to the second conductive pattern (see, e.g., CNP2 of FIG. 10) of the fifth conductive layer. Accordingly, the data signal may be provided to the second source region (see, e.g., SA2 of FIG. 5) of the second transistor M2 via the data line Dj and the second conductive pattern (see, e.g., CNP2 of FIG. 10).

The seventh conductive pattern CNP7 along with the sixth conductive pattern (see, e.g., CNP6 of FIG. 10) of the fifth conductive layer may electrically connect the sixth transistor M6 and the light emitting element (see, e.g., LD of FIG. 2) to each other. An end of the seventh conductive pattern CNP7 may be electrically connected to the sixth conductive pattern (see, e.g., CNP6 of FIG. 10), and another end of the seventh conductive pattern CNP7 may be electrically connected to the first electrode of the light emitting element (see, e.g., LD of FIG. 2) disposed on the seventh conductive pattern CNP7.

The first power line PL1, the data line Dj, and the seventh conductive pattern CNP7 may be formed of a same material in a same layer through a same process.

The pixel circuit (see, e.g., FIG. 2) may be implemented by the layout structure of the conductive layers and the semiconductor layers.

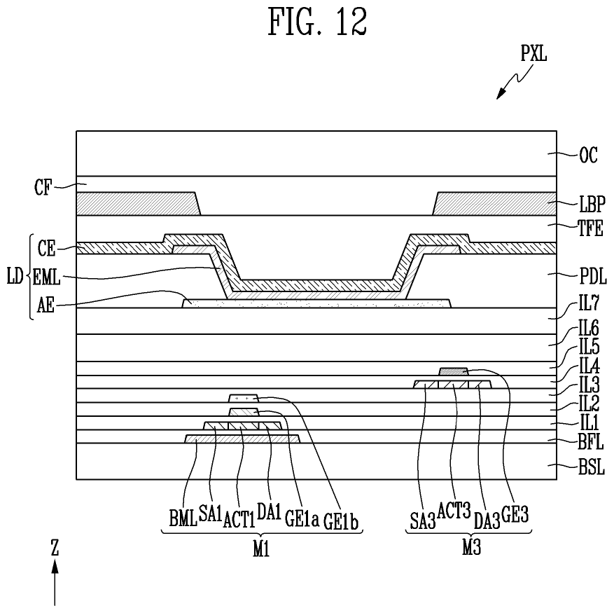

FIG. 12 is a schematic cross-sectional view illustrating a pixel. FIGS. 13 and 14 are schematic cross-sectional views taken along line A-A′ of FIG. 3. For convenience of description, a backplane structure including a pixel circuit will be described in FIGS. 13 and 14.

Referring to FIGS. 12 to 14, a base layer BSL may form a base surface. The base layer BSL may include a transparent insulating material and transmit light through the base layer BSL. The base layer BSL may be a rigid substrate or a flexible substrate. The rigid substrate may be, for example, one of a glass substrate, a quartz substrate, a glass ceramic substrate, and a crystalline glass substrate. The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the disclosure is not necessarily limited thereto.

A first conductive layer may be disposed on the base layer BSL. The first conductive layer may include a bottom metal layer BML. The first conductive layer may include a metal such as copper (Cu), molybdenum (Mo), aluminum (Al), titanium (Ti), the like, or a metal alloy, and have a single layer or multi-layers.

A buffer layer BFL may be disposed on the first conductive layer. The buffer layer BFL may be an inorganic insulating layer including an inorganic material. The buffer layer BFL may include at least one of silicon nitride (SiNₓ), silicon oxide (SiOₓ), silicon oxynitride (SiOₓN_{y}), and a metal oxide such as aluminum oxide (AlOₓ). In an embodiment, the buffer layer BFL may have a single layer, but the disclosure is not limited thereto. In another embodiment, the buffer layer BFL may have multi-layers including at least two layers. In case that the buffer layer BFL has multi-layers, the buffer layer BFL may include a same material or different materials.

A first semiconductor layer may be disposed on the buffer layer BFL. The first semiconductor layer may include a first active region ACT1, a first source region SA1, and a first drain region DA1 of a first transistor M1, and the like. The first semiconductor layer may be a poly-silicon semiconductor layer. For example, the first semiconductor layer may be formed through a low temperature poly-silicon (LTPS) process or the like.

A first insulating layer IL1 may be disposed on the first semiconductor layer. The first insulating layer IL1 may be an inorganic insulating layer including an inorganic material. The first insulating layer IL1 may include at least one of silicon nitride (SiNₓ), silicon oxide (SiOₓ), silicon oxynitride (SiOₓN_{y}), and a metal oxide such as aluminum oxide (AlOₓ). In an embodiment, the first insulating layer IL1 may have a single layer, but the disclosure is not limited thereto. In another embodiment, the first insulating layer IL1 may have multi-layers including at least two layers.

A second conductive layer may be disposed on the first insulating layer IL1. The second conductive layer may include a first gate electrode GE1a of the first transistor M1, a first electrode CB1 of a boost capacitor Cboost, and the like. The first gate electrode GE1a may overlap the first active region ACT1 in a plan view. The second conductive layer may have a single layer including at least one of copper (Cu), molybdenum (Mo), tungsten (W), aluminum neodymium (AlNd), titanium (Ti), aluminum (Al), silver (Ag), an alloy thereof, and a mixture thereof, or have a double-layered structure or a multi-layered structure including molybdenum (Mo), titanium (Ti), copper (Cu), aluminum (Al), silver (Ag), or an alloy thereof, which is a low-resistance material so as to decrease wiring resistance.

A second insulating layer IL2 may be disposed on the second conductive layer. The second insulating layer IL2 may be an inorganic insulating layer including an inorganic material. The second insulating layer IL2 may include at least one of silicon nitride (SiNₓ), silicon oxide (SiOₓ), silicon oxynitride (SiOₓN_{y}), and a metal oxide such as aluminum oxide (AlOₓ). In an embodiment, the second insulating layer IL2 may have a single layer, but the disclosure is not limited thereto. In another embodiment, the second insulating layer IL2 may have multi-layers including at least two layers.

A third conductive layer may be disposed on the second insulating layer IL2. The third conductive layer may include a second gate electrode GE1b of the first transistor M1, a second electrode CB2 of the boost capacitor Cboost, and the like. The second gate electrode GE1b may overlap the first gate electrode GE1a in a plan view. The second electrode CB2 of the boost capacitor Cboost may overlap the first electrode CB1 in a plan view. The third conductive layer may have a single layer including one of copper (Cu), molybdenum (Mo), tungsten (W), aluminum neodymium (AlNd), titanium (Ti), aluminum (Al), silver (Ag), an alloy thereof, and a mixture thereof, or have a double-layered or a multi-layered structure including molybdenum (Mo), titanium (Ti), copper (Cu), aluminum (Al), silver (Ag), the like, or an alloy thereof.

A third insulating layer IL3 may be disposed on the third conductive layer. The third insulating layer IL3 may be an inorganic insulating layer including an inorganic material. The third insulating layer IL3 may include at least one of silicon nitride (SiNₓ), silicon oxide (SiOₓ), silicon oxynitride (SiOₓN_{y}), and a metal oxide such as aluminum oxide (AlOₓ). In an embodiment, the third insulating layer IL3 may have a single layer, but the disclosure is not limited thereto. In another embodiment, the third insulating layer IL3 may have multi-layers including at least two layers.

A second semiconductor layer may be disposed on the third insulating layer IL3. The second semiconductor layer may include a third active region ACT3, a third source region SA3, and a third drain region DA3 of a third transistor M3, and the like. The second semiconductor layer may include an oxide semiconductor layer.

A fourth insulating layer IL4 may be disposed on the second semiconductor. The fourth insulating layer IL4 may be an inorganic insulating layer including an inorganic material. The fourth insulating layer IL4 may include at least one of silicon nitride (SiNₓ), silicon oxide (SiOₓ), silicon oxynitride (SiOₓN_{y}), and a metal oxide such as aluminum oxide (AlOₓ). In an embodiment, the fourth insulating layer IL4 may have a single layer, but the disclosure is not limited thereto. In another embodiment, the fourth insulating layer IL4 may have multi-layers including at least two layers.

A fourth conductive layer may be disposed on the fourth insulating layer IL4. The fourth conductive layer may include a gate electrode GE3 of the third transistor M3, a connection electrode CNE, and the like. The gate electrode GE3 of the third transistor M3 may overlap the third active region ACT3 in a plan view.

Referring to FIG. 13, the connection electrode CNE may be electrically connected to the first gate electrode GE1a of the first transistor M1 and the second electrode CB2 of the boost capacitor Cboost. In an embodiment, an end of the connection electrode CNE may contact the first gate electrode GE1a of the first transistor M1 through a contact hole penetrating the second insulating layer IL2, the third insulating layer IL3, and the fourth insulating layer IL4. The end of the connection electrode CNE may contact the first gate electrode GE1a of the first transistor M1 through an opening of an upper electrode UE of a storage capacitor (see, e.g., Cst of FIG. 2). Another end of the connection electrode CNE may contact the second electrode CB2 of the boost capacitor Cboost through a contact hole penetrating the third insulating layer IL3 and the fourth insulating layer IL4. The first electrode CB1 of the boost capacitor Cboost may be formed with the second conductive layer, the second electrode CB2 of the boost capacitor Cboost may be formed with the third conductive layer disposed adjacent to the second conductive layer, the connection electrode CNE may be formed with the fourth conductive layer, and a charge capacity of the boost capacitor Cboost may be secured in a space (e.g., a limited or selectable space).

The fourth conductive layer may have a single layer including one of copper (Cu), molybdenum (Mo), tungsten (W), aluminum neodymium (AlNd), titanium (Ti), aluminum (Al), silver (Ag), an alloy thereof, and a mixture thereof, or have a double-layered structure or a multi-layered structure including molybdenum (Mo), titanium (Ti), copper (Cu), aluminum (Al), silver (Ag), the like, or an alloy thereof.

A fifth insulating layer IL5 may be disposed on the fourth conductive layer. The fifth insulating layer IL5 may be an inorganic insulating layer including an inorganic material. The fifth insulating layer IL5 may include at least one of silicon nitride (SiNₓ), silicon oxide (SiOₓ), silicon oxynitride (SiOₓN_{y}), and a metal oxide such as aluminum oxide (AlOₓ). In an embodiment, the fifth insulating layer IL5 may have a single layer, but the disclosure is not limited thereto. In another embodiment, the fifth insulating layer IL5 may have multi-layers including at least two layers.

A fifth conductive layer may be disposed on the fifth insulating layer IL5. Referring to FIG. 14, a connection electrode CNE′ may be formed with the fifth conductive layer. The connection electrode CNE′ may be electrically connected to the first gate electrode GE1a of the first transistor M1 and the second electrode CB2 of the boost capacitor Cboost. In an embodiment, an end of the connection electrode CNE′ may contact the first gate electrode GE1a of the first transistor M1 through a contact hole penetrating the second insulating layer IL2, the third insulating layer IL3, the fourth insulating layer IL4, and the fifth insulating layer IL5. The end of the connection electrode CNE′ may contact the first gate electrode GE1a of the first transistor M1 disposed under the connection electrode CN′ through the opening of the upper electrode UE of the storage capacitor (see, e.g., Cst of FIG. 2). Another end of the connection electrode CNE′ may contact the second electrode CB2 of the boost capacitor Cboost through a contact hole penetrating the third insulating layer IL3, the fourth insulating layer IL4, and the fifth insulating layer IL5. The first electrode CB1 of the boost capacitor Cboost may be formed with the second conductive layer, the second electrode CB2 of the boost capacitor Cboost may be formed with the third conductive layer disposed adjacent to the second conductive layer, and the connection electrode CNE′ may be formed with the fifth conductive layer, and the charge capacity of the boost capacitor Cboost may be secured in a space (e.g., a limited or selectable space).

The fifth conductive layer may have a single layer including at least one of copper (Cu), molybdenum (Mo), tungsten (W), aluminum neodymium (AlNd), titanium (Ti), aluminum (Al), silver (Ag), an alloy thereof, and a mixture thereof, or have a double-layered structure or a multi-layered structure including molybdenum (Mo), titanium (Ti), copper (Cu), aluminum (Al), silver (Ag), or an alloy thereof.

A sixth insulating layer IL6 may be disposed on the fifth conductive layer. The sixth insulating layer IL6 may be an inorganic layer (or inorganic insulating layer) including an inorganic material or an organic layer (or organic insulating layer) including an organic material. The sixth insulating layer IL6 may include, for example, at least one of silicon oxide (SiOₓ), silicon nitride (SiNₓ), silicon oxynitride (SiOₓN_{y}), and a metal oxide such as aluminum oxide (AlOₓ). The sixth insulating layer IL6 may include, for example, at least one of an acrylic resin, an epoxy resin, a phenolic resin, a polyamide resin, a polyimide resin, an unsaturated polyester resin, a poly-phenylene ether resin, a poly-phenylene sulfide resin, and a benzocyclobutene resin.

A sixth conductive layer may be disposed on the sixth insulating layer IL6. The sixth conductive layer may have a single layer including at least one of copper (Cu), molybdenum (Mo), tungsten (W), aluminum neodymium (AlNd), titanium (Ti), aluminum (Al), silver (Ag), an alloy thereof, and a mixture thereof, or have a double-layered structure or a multi-layered structure including molybdenum (Mo), titanium (Ti), copper (Cu), aluminum (Al), silver (Ag), the like, or an alloy thereof.

A seventh insulating layer IL7 may be disposed on the sixth conductive layer. The seventh insulating layer IL7 may be an inorganic layer (or inorganic insulating layer) including an inorganic material or an organic layer (or organic insulating layer) including an organic material. The seventh insulating layer IL7 may include, for example, at least one of silicon oxide (SiOₓ), silicon nitride (SiNₓ), silicon oxynitride (SiOₓN_{y}), and a metal oxide such as aluminum oxide (AlOₓ). The seventh insulating layer IL7 may include, for example, at least one of an acrylic resin, an epoxy resin, a phenolic resin, a polyamide resin, a polyimide resin, an unsaturated polyester resin, a poly-phenylene ether resin, a poly-phenylene sulfide resin, and a benzocyclobutene resin.

A first electrode AE (or anode electrode) of a light emitting element LD may be disposed on the seventh insulating layer IL7. The first electrode AE may be electrically connected to the sixth conductive layer through a contact hole penetrating the seventh insulating layer IL7 and be electrically connected to a transistor T disposed under the first electrode AE.

A bank PDL may be disposed on the first electrode AE. The bank PDL may define (or partition) an emission area of each pixel PXL. The bank PDL may include an opening exposing a first electrode AE of each pixel PXL.

The bank PDL may be an organic insulating layer including an organic material. The bank PDL may include an acrylic resin, an epoxy resin, a phenolic resin, a polyamide resin, a polyimide resin, the like, or a combination thereof.

In an embodiment, the bank PDL may include a light absorption material, or have a light absorber applied on the bank PDL, and absorb light introduced from an outside. In an embodiment, the bank PDL may include a carbon-based black pigment. However, the disclosure is not necessarily limited thereto, and in another embodiment, the bank PDL may include an opaque metal material such as chromium (Cr), molybdenum (Mo), an alloy (MoTi) of molybdenum and titanium, tungsten (W), vanadium (V), niobium (Nb), tantalum (Ta), manganese (Mn), cobalt (Co), nickel (Ni), the like, or a combination thereof, which has a high light absorption rate.

A light emitting layer EML of the light emitting element LD may be disposed on the first electrode AE. The light emitting layer EML may be disposed on the first electrode AE exposed by the bank PDL. A second electrode CE (or cathode electrode) of the light emitting element LD may be disposed on the light emitting layer EML. The second electrode CE may be disposed throughout the whole of the pixel PXL. In an embodiment, the second electrode CE may be a common electrode, but the disclosure is not necessarily limited thereto.

The second electrode CE may be configured with a metal layer such as silver (Ag), magnesium (Mg), aluminum (Al), platinum (Pt), palladium (Pd), gold (Au), nickel (Ni), neodymium (Nd), iridium (Ir), chromium (Cr), the like, or an alloy thereof, and/or a transparent conductive layer such as indium tin oxide (ITO), indium zinc oxide (IZO), zinc oxide (ZnO), indium tin zinc oxide (ITZO), the like, or a combination thereof. In an embodiment, the second electrode CE may have multi-layers including at least two layers including a metal thin layer. For example, the second electrode CE may include a triple layer of ITO/Ag/ITO.

A thin film encapsulation layer TFE may be disposed on the second electrode CE. The thin film encapsulation layer TFE may have a single-layer structure or a multi-layered structure. The thin film encapsulation layer TFE may include multiple insulating layers covering the light emitting element LD. The thin film encapsulation layer TFE may include at least one inorganic layer and at least one organic layer. For example, the thin film encapsulation layer TFE may have a structure in which an inorganic layer and an organic layer are alternately stacked. In an embodiment, the thin film encapsulation layer TFE may be an encapsulation substrate disposed on the light emitting element LD and be bonded to the base layer BSL by a sealant.

A light blocking layer LBP may be disposed on the thin film encapsulation layer TFE. The light blocking layer LBP may include a light blocking material and prevent light leakage and color mixture. In an embodiment, the light blocking layer LBP may include a black matrix BM, but the disclosure is not necessarily limited thereto. In another embodiment, the light blocking layer LBP may include a carbon black (CB) and/or titan black (TiBK).

A color filter layer CF may be disposed on the light blocking layer LBP. The color filter layer CF may include a color filter according to a color of each pixel PXL. The color filter layer CF including the color filter according to the color of each pixel PXL may be disposed, and a full-color image may be displayed. In an embodiment, the color filter layer CF may include a first color filter, a second color filter, and a third color filter. The first color filter may include a color filter material for selectively transmitting light of a first color (or red) through the first color filter. For example, in case that the first pixel PXL1 is a red pixel, the first color filter may include a red color filter material. The second color filter may include a color filter material for selectively transmitting light of a second color (or green) through the second color filter. For example, in case that the second pixel PXL2 is a green pixel, the second color filter may include a green color filter material. The third color filter may include a color filter material for selectively transmitting light of a third color (or blue) through a color filter material. For example, in case that the third pixel PXL3 is a blue pixel, the third color filter may include a blue color filter material.

An overcoat layer OC may be disposed on the color filter layer CF. The overcoat layer OC may be provided throughout a whole (or an entire portion) of the pixel PXL. The overcoat layer OC may cover a lower member including the color filter layer CF. The overcoat layer OC may prevent moisture or air from infiltrating into the lower member. The overcoat layer OC may protect the lower member from a foreign matter such as dust or the like.

In an embodiment, the overcoat layer OC may include an organic material such as an acrylic resin, an epoxy resin, a phenolic resin, a polyamide resin, a polyimide resin, an unsaturated polyester resin, a poly-phenylene ether resin, a poly-phenylene sulfide resin, a benzocyclobutene (BCB), or the like. However, the disclosure is not necessarily limited thereto, and in another embodiment, the overcoat layer OC may include various kinds of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), titanium oxide (TiOₓ), the like, or a combination thereof.

In accordance with the disclosure, a boost capacitor Cboost may be formed with adjacent conductive layers, and a charge capacity of the boost capacitor Cboost may be secured in a space (e.g., a limited or selectable space).

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode of a boost capacitor disposed on a base layer;
a second electrode of the boost capacitor disposed on the first electrode of the boost capacitor;
a gate electrode of a driving transistor, disposed on the base layer; and
a connection electrode electrically connecting the gate electrode of the driving transistor and the second electrode of the boost capacitor to each other, wherein
the second electrode of the boost capacitor is disposed between the first electrode of the boost capacitor and the connection electrode, and
the gate electrode of the driving transistor and the first electrode of the boost capacitor are disposed in a same layer.

2. The display device of claim 1, further comprising:
a first insulating layer disposed between the base layer, and the gate electrode of the driving transistor and the first electrode of the boost capacitor.

3. The display device of claim 2, further comprising:
a semiconductor layer disposed between the base layer and the first insulating layer.

4. The display device of claim 1, further comprising:
a second insulating layer disposed between the first electrode of the boost capacitor and the second electrode of the boost capacitor.

5. The display device of claim 4, further comprising:
a third insulating layer disposed between the second electrode of the boost capacitor and the connection electrode.

6. The display device of claim 5, wherein the connection electrode contacts the second electrode of the boost capacitor through a contact hole penetrating the third insulating layer.

7. The display device of claim 5, wherein the connection electrode contacts the gate electrode of the driving transistor through a contact hole penetrating the second insulating layer and the third insulating layer.

8. The display device of claim 5, further comprising:
a fourth insulating layer disposed between the third insulating layer and the connection electrode.

9. The display device of claim 8, wherein the connection electrode contacts the second electrode of the boost capacitor through a contact hole penetrating the third insulating layer and the fourth insulating layer.

10. The display device of claim 8, wherein the connection electrode contacts the gate electrode of the driving transistor through a contact hole penetrating the second insulating layer, the third insulating layer, and the fourth insulating layer.

11. A display device comprising:
a gate electrode of a driving transistor and a first electrode of a boost capacitor, each disposed on a semiconductor layer;
a second electrode of the boost capacitor disposed on the first electrode of the boost capacitor; and
a connection electrode disposed on the gate electrode of the driving transistor,
wherein the connection electrode is electrically connected to the gate electrode of the driving transistor and the second electrode of the boost capacitor.

12. The display device of claim 11, wherein the gate electrode of the driving transistor and the first electrode of the boost capacitor are disposed in a same layer.

13. The display device of claim 11, further comprising:
a first insulating layer disposed between the semiconductor layer, and the gate electrode of the driving transistor and the first electrode of the boost capacitor.

14. The display device of claim 11, further comprising:
a second insulating layer disposed between the first electrode of the boost capacitor and the second electrode of the boost capacitor.

15. The display device of claim 14, further comprising:
a third insulating layer disposed between the second electrode of the boost capacitor and the connection electrode.

16. The display device of claim 15, wherein the connection electrode contacts the second electrode of the boost capacitor through a contact hole penetrating the third insulating layer.

17. The display device of claim 15, wherein the connection electrode contacts the gate electrode of the driving transistor through a contact hole penetrating the second insulating layer and the third insulating layer.

18. The display device of claim 15, further comprising:
a fourth insulating layer disposed between the third insulating layer and the connection electrode.

19. The display device of claim 18, wherein the connection electrode contacts the second electrode of the boost capacitor through a contact hole penetrating the third insulating layer and the fourth insulating layer.

20. The display device of claim 18, wherein the connection electrode contacts the gate electrode of the driving transistor through a contact hole penetrating the second insulating layer, the third insulating layer, and the fourth insulating layer.
